(19) United States
(12) Patent Application Publication
(10) Pub. No.: US 2026/0277125 A1
(43) Pub. Date: Sep. 17, 2026

(54) ALIGNMENT APPARATUS, LITHOGRAPHY APPARATUS, AND ARTICLE MANUFACTURING METHOD

(71) Applicant: CANON KABUSHIKI KAISHA, Tokyo (JP)

(72) Inventors: TAKEHIKO UENO, Tochigi (JP); NOZOMU HAYASHI, Tochigi (JP)

(21) Appl. No.: 19/565,262

(22) Filed: Mar. 12, 2026

(30) Foreign Application Priority Data
Mar. 17, 2025 (JP) 2025-042625

(51) Int. Cl. G03F 9/00; H10P 72/50; H10W 46/00

(52) U.S. Cl. CPC G03F 9/7046; G03F 9/7084; H10P 72/53; H10W 46/301

(57) ABSTRACT

An alignment apparatus for performing alignment between an original and a substrate, the original having a pattern and a mark, and the substrate having a convex portion to which the pattern is to be transferred. The alignment apparatus includes an image capturing device configured to capture, through one of the original and the substrate, an image of the other of the original and the substrate, and a controller configured to control the alignment based on an image obtained by the image capturing device. The image includes a part of an outer edge of the convex portion of the substrate and the mark of the original.

### BACKGROUND

### Field of the Technology

The present disclosure relates to an alignment apparatus, a lithography apparatus, and an article manufacturing method.

### Description of the Related Art

As one of lithography techniques for manufacturing an article such as a semiconductor device or a magnetic storage medium, an imprint technique for transferring a concave-convex pattern (a pattern having concave and convex portions) of an original (mold) to a composition on a substrate has received a great deal of attention. For example, one of the imprint techniques is a photocuring method. In an imprint apparatus that employs the photocuring method, in a state in which an original and a composition on a substrate are in contact, the composition is cured by irradiating it with light (for example, ultraviolet light), and the original is separated from the cured composition. A pattern on a nanometer order can thus be formed in the composition on the substrate.

This imprint technique is sometimes used to, for example, produce a replica mold from a master mold. In the imprint technique for producing a replica mold, the concave-convex pattern of an original that is a master mold can be transferred to a convex portion provided on a substrate that is a blank mold. At this time, to accurately transfer the concave-convex pattern of the original to the convex portion of the substrate, it is important to accurately perform alignment between the concave-convex pattern of the mold and the convex portion of the substrate.

Japanese Patent Laid-Open No. 2013-62286 proposes an imprint apparatus in which a measurement unit configured to measure the distance to a blank mold is provided, and the measurement unit that is being moved with respect to the blank mold is caused to measure the distance, thereby obtaining the height distribution of the convex portion provided on the blank mold. In Japanese Patent Laid-Open No. 2013-62286, alignment between the pattern of the master mold and the convex portion of the blank mold is performed based on the height distribution of the convex portion of the blank mold.

For alignment between an original (for example, a master mold) having a pattern and a substrate (for example, a blank mold) having a convex portion, the alignment accuracy is required to be further improved.

### SUMMARY

The present disclosure provides a technique advantageous in terms of alignment accuracy between an original having a pattern and a substrate having a convex portion.

According to one aspect of the present disclosure, there is provided an alignment apparatus for performing alignment between an original and a substrate, the original having a pattern and a mark, and the substrate having a convex portion to which the pattern is to be transferred, comprising: an image capturing device configured to capture, through one of the original and the substrate, an image of the other of the original and the substrate; and a controller configured to control the alignment based on an image obtained by the image capturing device, the image including a part of an outer edge of the convex portion of the substrate and the mark of the original.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic view showing an example of the configuration of an imprint apparatus according to the first embodiment;

FIG. 2 is a flowchart showing imprint processing for producing a replica mold in the first embodiment;

FIG. 3 is a view for explaining an alignment driving amount determination method;

FIG. 4 is a view for explaining an alignment driving amount determination method;

FIG. 5 is a flowchart showing imprint processing for producing a replica mold in the second embodiment; and

FIG. 6 is a schematic view showing an example of the configuration of an imprint apparatus according to the third embodiment.

### DESCRIPTION OF THE EMBODIMENTS

Hereinafter, embodiments will be described in detail with reference to the attached drawings. Note that, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which an XY plane is defined by directions parallel to the surface of a substrate (convex portion), unless otherwise specified. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are RotX, RotY, and RotZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the RotX-axis, the RotY-axis, and the RotZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the RotX-, RotY-, and RotZ-axes.

A lithography apparatus according to the present disclosure is an apparatus that forms a pattern on a substrate using an original. Examples of the lithography apparatus are an exposure apparatus that exposes a substrate to transfer the pattern of an original (mask) onto the substrate, and an imprint apparatus that forms a pattern on an imprint material on a substrate using an original (mold). A description will be made below by exemplifying an imprint apparatus as a lithography apparatus.

### First Embodiment

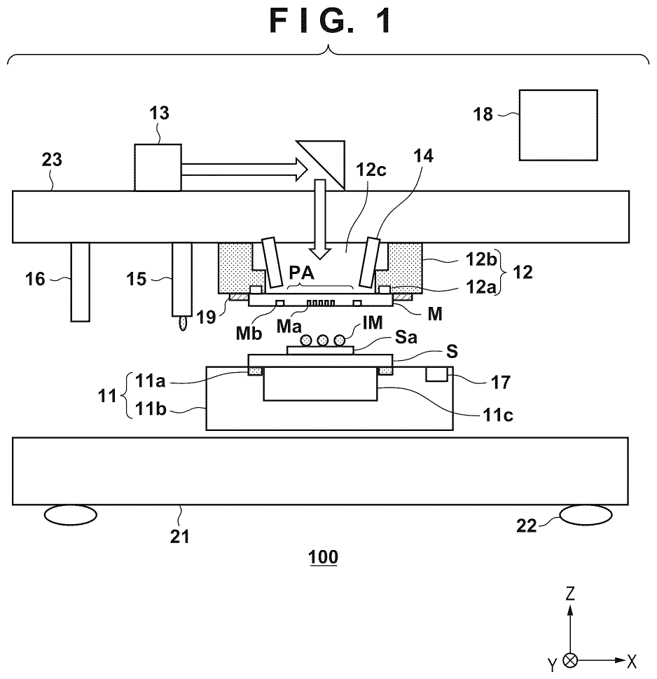

The first embodiment according to the present disclosure will be described. FIG. 1 schematically shows an example of the configuration of an imprint apparatus 100 according to this embodiment. The imprint apparatus 100 is a lithography apparatus that shapes an imprint material IM (composition) on a substrate S using an original M (mold) and can be used to manufacture a device such as a semiconductor device or a magnetic storage medium as an article. The imprint apparatus 100 performs processing of bringing the uncured imprint material IM supplied onto the substrate S into contact with the original M and applying curing energy to the imprint material IM, thereby forming, on the substrate S, a pattern of a cured product to which the pattern of the original M is transferred. This processing can be called imprint processing. In this embodiment, an example in which a photocuring method of curing the imprint material IM by irradiating the imprint material IM on the substrate S with light (for example, ultraviolet light) is employed will be described.

As the imprint material IM, a curable composition (to be also referred to as a resin in an uncured state) to be cured by receiving curing energy is used. As the curing energy, an electromagnetic wave, heat, or the like can be used. The electromagnetic wave can be, for example, light selected from the wavelength range of 10 nm or more and 1 mm or less, for example, infrared light, visible light, or ultraviolet light. The curable composition can be a composition cured by light irradiation or heating. Among these, the photocurable composition cured by light irradiation contains at least a polymerizable compound and a photopolymerization initiator, and may further contain a nonpolymerizable compound or a solvent, as needed. The nonpolymerizable compound is at least one type of material selected from the group consisting of a sensitizer, a hydrogen donor, an internal mold release agent, a surfactant, an antioxidant, a polymer component, and the like. The imprint material IM can be arranged on the substrate S in a droplet shape or in an island or film shape formed by connecting a plurality of droplets. The viscosity (the viscosity at 25° C.) of the imprint material IM can be, for example, 1 mPa·s or more and 100 mPa·s or less.

As the material of the substrate S, for example, glass, a ceramic, a metal, a semiconductor, a resin, or the like can be used. A member made of a material different from that of the substrate S may be provided on the surface of the substrate S, as needed.

The substrate S is, for example, a silicon wafer, a compound semiconductor wafer, or silica glass. Also, as the material of the original M, for example, glass, a ceramic, a metal, a semiconductor, a resin, or the like can be used. As an example, the original M may be rectangular in the outer peripheral shape and may be made of a material such as silica glass which can pass light (ultraviolet light). In a partial region of the surface of the original M facing the substrate S, a concave-convex pattern Ma (to be sometimes simply referred to as a pattern Ma hereinafter) such as a circuit pattern to be transferred onto the substrate S is three-dimensionally formed.

The imprint apparatus 100 according to this embodiment can be used not only to manufacture a device such as a semiconductor device but also to produce a replica mold from a master mold. In imprint processing for producing a replica mold, the concave-convex pattern of the original M that is a master mold is transferred to a mesa portion Sa (convex portion) provided on the substrate S that is a blank mold. From the master mold, a plurality of replica molds having a concave-convex pattern of the same shape can be produced by imprint processing.

“Replica mold” is a mold which is manufactured based on the concave-convex pattern of the master mold and to which the concave-convex pattern of the master mold is transferred, and can be used in imprint processing at the time of device manufacturing. In some cases, the replica mold is produced using a previously created replica mold as a master mold. Also, “blank mold” is a substrate to which the concave-convex pattern of the master mold is not transferred yet. On the blank mold, a target transfer region to which the concave-convex pattern of the master mold should be transferred is formed as a mesa portion (convex portion), and the concave-convex pattern of the master mold is transferred later by imprint processing to the mesa portion as the target transfer region. The blank mold that has undergone the imprint processing is the replica mold.

An example in which a master mold is used as the original M and a blank mold is used as the substrate S will be described below. On the substrate S as the blank mold, the mesa portion Sa (convex portion) to which a pattern Ma of the original M as the master mold should be transferred is formed. The pattern Ma is arranged in a region (to be sometimes referred to as a pattern region PA hereinafter) of the original M, which is caused to face the mesa portion Sa of the substrate S in imprint processing. Also, on the original M, a mark Mb (alignment mark) to be aligned with the mesa portion Sa of the substrate S is arranged outside the pattern region PA.

As shown in FIG. 1, the imprint apparatus 100 according to this embodiment can include a first positioning mechanism 11, a second positioning mechanism 12, a light irradiation unit 13, an image capturing device 14, a liquid supply unit 15, a first height measurement unit 16, a second height measurement unit 17, and a controller 18.

The first positioning mechanism 11 is a mechanism that performs positioning of one of the original M (master mold) and the substrate S (blank mold) and, in this embodiment, performs positioning of the substrate S. The first positioning mechanism 11 according to this embodiment can include a first holder 11a that holds the substrate S, and a first driving mechanism (driver) 11b that drives the substrate S by driving the first holder 11a. The first holder 11a is configured to hold the outer peripheral portion of the substrate S using a vacuum suction force or electrostatic power. The first driving mechanism 11b supports the first holder 11a and is configured to drive the first holder 11a and the substrate S in the X and Y directions by moving on a surface plate 21 installed via a damper 22. The first driving mechanism 11b may be configured to drive the substrate S not only in the X and Y directions but also in the Z direction, the RotX direction, the RotY direction, and/or the RotZ direction.

Also, in the first positioning mechanism 11, an opening region 11c is provided at a position corresponding to the central portion of the substrate S. The opening region 11c forms an enclosed space when the substrate S is held by the first holder 11a, and the internal pressure of the opening region 11c is adjusted by a pressure adjustment unit (not shown) including a vacuum pump or the like. For example, when the internal pressure of the opening region 11c is adjusted such that it is larger than the pressure outside, the substrate S (mesa portion Sa) can be deformed into a convex shape deflected toward the original M. If the original M starts contacting the imprint material IM on the substrate S in a state in which the substrate S is deformed into the convex shape, confinement of bubbles, which cause pattern defects, in the imprint material can be reduced.

The second positioning mechanism 12 is a mechanism that performs positioning of the other of the original M (master mold) and the substrate S (blank mold) and, in this embodiment, performs positioning of the original M. The second positioning mechanism 12 according to this embodiment can include a second holder 12a that holds the original M, and a second driving mechanism 12b that drives the original M by driving the second holder 12a. The second holder 12a is configured to hold the outer peripheral portion of the original M using a vacuum suction force or electrostatic power. The second driving mechanism 12b supports the second holder 12a and is also supported by a frame 23, and is configured to drive the second holder 12a and the original M in the Z direction. The second driving mechanism 12b may be configured to drive the original M not only in the Z direction but also in the X direction, the Y direction, the RotX direction, the RotY direction, and/or the RotZ direction.

Also, in the second positioning mechanism 12, an opening region 12c is provided at a position corresponding to the central portion of the original M. The opening region 12c forms an enclosed space when the original M is held by the second holder 12a, and the internal pressure of the opening region 12c is adjusted by a pressure adjustment unit (not shown) including a vacuum pump or the like. For example, when the internal pressure of the opening region 12c is adjusted such that it is larger than the pressure outside, the pattern region PA of the original M can be deformed into a convex shape deflected toward the substrate S. If the original M starts contacting the imprint material IM on the substrate S in a state in which the original Mis deformed into the convex shape, confinement of bubbles, which cause pattern defects, in the imprint material can be reduced.

Here, the first positioning mechanism 11 (first driving mechanism 11b) and the second positioning mechanism 12 (second driving mechanism 12b) constitute a driving mechanism that relatively drives the original M and the substrate S to change the relative position and/or the relative posture between the original M and the substrate S. Relative driving of the original M and the substrate S by the driving mechanism includes driving for bringing the original M into contact with the imprint material IM on the substrate S and driving for separating the original M from the cured imprint material IM on the substrate S. Also, relative driving of the original M and the substrate S by the driving mechanism includes alignment between the original M (pattern Ma) and the substrate S (mesa portion Sa).

Alignment between the original M and the substrate S can be performed by relatively driving the original M and the substrate S such that the position error and/or the shape error between the original M and the substrate S is reduced. The position error can include deviation of the relative position and/or relative posture between the original M (pattern Ma) and the substrate S (mesa portion Sa) in the X direction, the Y direction, the Z direction, the RotX direction, the RotY direction, and/or the RotZ direction. The shape error can include skew and/or magnification error between the original M (pattern Ma) and the substrate S (mesa portion Sa). The shape error may be corrected by a shape correction unit 19 in addition to or in place of the first positioning mechanism 11 and the second positioning mechanism 12. The shape correction unit 19 is a mechanism that corrects the shape of the pattern region PA of the original M or the mesa portion Sa of the substrate S by applying a force to the side surface of the original M or the substrate S held by the first positioning mechanism 11.

The light irradiation unit 13 irradiates the imprint material IM with light through one of the original M and the substrate S in a state in which the original M and the substrate S are in contact while interposing the imprint material IM therebetween, thereby curing the imprint material. The light irradiation unit 13 according to this embodiment is configured to irradiate the imprint material IM with light through the original M held by the second positioning mechanism 12.

The image capturing device 14 is configured to capture, through one of the original M and the substrate S, an image of the other of the original M and the substrate S. The image capturing device 14 according to this embodiment is configured to capture an image of the substrate S held by the first positioning mechanism 11 through the original M held by the second positioning mechanism 12. The image capturing device 14 is a scope used for alignment between the original M and the substrate S (mesa portion Sa), and is sometimes called an alignment scope. As will be described later in detail, the image capturing device 14 according to this embodiment captures an image including a part of the outer edge of the mesa portion Sa of the substrate S and the mark Mb of the original M, and transmits the thus obtained image (image data) to the controller 18. The controller 18 controls alignment between the original M (pattern Ma) and the substrate S (mesa portion Sa) based on the image obtained by the image capturing device 14.

The liquid supply unit 15 supplies (arranges) the imprint material IM onto one of the original M and the substrate S held by the first positioning mechanism 11. The liquid supply unit 15 according to this embodiment supplies the imprint material IM onto the substrate S held by the first positioning mechanism 11. The liquid supply unit 15 includes a dispenser that discharges the imprint material IM as droplets and, in a state in which the substrate S is being moved under the dispenser by the first positioning mechanism 11, discharges the imprint material IM from the dispenser as a plurality of droplets. The imprint material IM is thus arranged as a plurality of droplets on the substrate S.

The first height measurement unit 16 is supported by the frame 23 and measures the surface height of one of the original M and the substrate S held by the first positioning mechanism 11. The first height measurement unit 16 according to this embodiment measures the surface height of the substrate S held by the first positioning mechanism 11. Also, the second height measurement unit 17 is supported by the first positioning mechanism 11 (first driving mechanism 11b) and measures the surface height of the other of the original M and the substrate S held by the second positioning mechanism 12. The second height measurement unit 17 according to this embodiment measures the surface height of the original M held by the second positioning mechanism 12. Each of the first height measurement unit 16 and the second height measurement unit 17 includes, for example, a laser interferometer that detects the distance to the target (the original M or the substrate S), and can be configured to measure the surface height of the target based on the distance detected by the laser interferometer.

The controller 18 is formed by an information processing apparatus (computer) including a processor such as, for example, a Central Processing Unit (CPU) and a memory, and controls imprint processing by controlling the units of the imprint apparatus 100. The controller 18 according to this embodiment can also include a function of controlling alignment between the original M and the substrate S based on the image obtained by the image capturing device 14. That is, the image capturing device 14 and the controller 18 according to this embodiment form an alignment apparatus that performs alignment between the original M and the substrate S. The alignment apparatus may include a driving mechanism (the first positioning mechanism 11 and the second positioning mechanism 12) that relatively drives the original M and the substrate S. Note that the controller 18 may be formed by, for example, a PLD (short for Programmable Logic Device) such as an FPGA (short for Field Programmable Gate Array), an ASIC (short for Application Specific Integrated Circuit), a general-purpose computer with a program installed, or a combination of some or all of these.

[Imprint Processing]

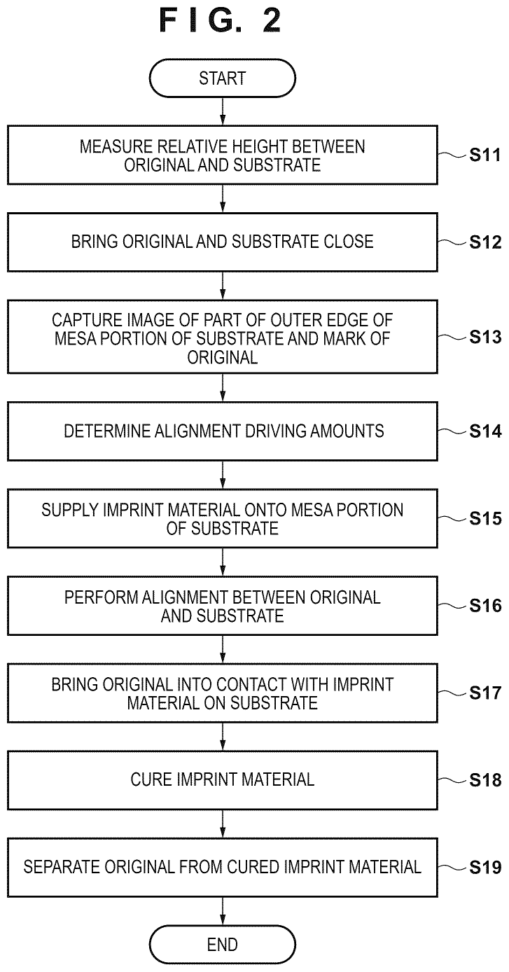

Imprint processing for producing a replica mold by the imprint apparatus 100 according to this embodiment will be described next. FIG. 2 is a flowchart showing imprint processing for producing a replica mold in this embodiment. The flowchart shown in FIG. 2 can be executed by the controller 18.

In step S11, the controller 18 measures the relative height between the original M and the substrate S. More specifically, the controller 18 measures the surface height of the substrate S (mesa portion Sa) using the first height measurement unit 16 and also measures the surface height of the original M (pattern region PA) using the second height measurement unit 17. The relative height between the surface of the original M and the surface of the substrate S (mesa portion Sa) can thus be measured.

In step S12, using the first positioning mechanism 11, the controller 18 arranges the substrate S under the original M and brings the mark Mb of the original M close to the mesa portion Sa of the substrate S. For example, based on the relative height between the original M and the substrate S measured in step S11, the controller 18 relatively drives the original M and the substrate S in the Z direction such that the mark Mb of the original M and the mesa portion Sa of the substrate S are fitted in the focal depth (focus range) of the image capturing device 14. The relative driving of the original M and the substrate S in the Z direction can be performed using the first positioning mechanism 11 and/or the second positioning mechanism 12. Note that the original M and the substrate S, which have undergone step S12, are not in contact with each other.

In step S13, in the state in which the original M and the substrate S are not in contact, the controller 18 captures an image including a part of the outer edge of the mesa portion Sa of the substrate S and the mark Mb of the original M by the image capturing device 14. In this embodiment, in a state in which both the part of the outer edge of the mesa portion Sa of the substrate S and the mark Mb of the original M are included within the field (image capturing field) of view of the image capturing device 14, the controller 18 simultaneously captures the image of these by the image capturing device 14. The image obtained by the image capturing device 14 thus includes the part of the outer edge of the mesa portion Sa and the mark Mb of the original M. If a plurality of marks Mb are provided on the original M, image capturing by the image capturing device 14 can be performed for each mark Mb.

Here, the mark Mb of the original M is arranged outside the pattern region PA of the original M such that both a part of the outer edge of the mesa portion Sa of the substrate S and the mark Mb are included within the field of view of the image capturing device 14. As described above, the pattern region PA is a region of the original M, which is caused to face the mesa portion Sa of the substrate S in imprint processing, and has the pattern Ma. Also, to reduce the influence of focus variations of the outer edge of the mesa portion Sa of the substrate S, the mark Mb can be arranged in a plane that has the same height as the surface with the pattern Ma arranged thereon. In the X and Y directions, the size of the mesa portion Sa of the substrate S is equal to or larger than the size of the region occupied by the pattern Ma on the original M and is also smaller than the size of the region further including the mark Mb.

In step S14, the controller 18 determines (calculates), based on the image obtained by the image capturing device 14 in step S13, relative driving amounts for relatively driving the original M and the substrate S for alignment between the original M (pattern Ma) and the substrate S (mesa portion Sa). The relative driving amount will sometimes be referred to as “alignment driving amount” hereinafter. Based on the image obtained by the image capturing device 14, the controller 18 can determine the alignment driving amounts such that the position error and/or the shape error between the original M (pattern Ma) and the substrate S (mesa portion Sa) is reduced. Here, alignment between the original M and the substrate S can include at least a shift (X and Y directions) and a rotation (RotZ direction) of the original M and the substrate S. Hence, marks Mb of a number that enables determination of the alignment driving amounts concerning the shift and rotation of the original M and the substrate S can be provided on the original M.

In step S15, the controller 18 supplies the imprint material IM onto the mesa portion Sa of the substrate S using the liquid supply unit 15 (supply step). For example, the controller 18 causes the liquid supply unit 15 (dispenser) to discharge the imprint material IM as a plurality of droplets while moving the mesa portion Sa of the substrate S by the first positioning mechanism 11 under the liquid supply unit 15. The imprint material IM can thus be supplied as a plurality of droplets onto the mesa portion Sa of the substrate S.

In step S16, the controller 18 performs alignment between the original M and the substrate S based on the alignment driving amounts determined in step S14 (alignment step). More specifically, the controller 18 corrects the relative position between the original M and the substrate S when the substrate S is arranged under the original M in step S12 by the alignment driving amounts determined in step S14. The controller 18 then relatively drives the original M and the substrate S using the first positioning mechanism 11 and/or the second positioning mechanism 12 such that a relative position corrected by the alignment driving amounts is obtained. In a state in which the original M and the substrate S are thus aligned, the pattern Ma of the original M is transferred onto the substrate S (mesa portion Sa) in subsequent steps S17 to S19.

In step S17, the controller 18 decreases the interval between the original M and the substrate S, thereby bringing the original M into contact with the imprint material IM on the substrate S (mesa portion Sa) (contact step). The operation of decreasing the interval between the original M and the substrate S can be performed using the first positioning mechanism 11 and/or the second positioning mechanism 12. Next, in step S18, in a state in which the original M and the imprint material IM on the substrate S (mesa portion Sa) are in contact, the controller 18 cures the imprint material IM (curing step). More specifically, the controller 18 controls the light irradiation unit 13 to irradiate the imprint material IM with light, thereby curing the imprint material IM.

In step S19, the controller 18 increases the interval between the original M and the substrate S, thereby separating the original M from the cured imprint material IM on the substrate S (mesa portion Sa) (separation step). The operation of increasing the interval between the original M and the substrate S can be performed using the first positioning mechanism 11 and/or the second positioning mechanism 12. A pattern formed by the cured product of the imprint material IM to which the pattern Ma of the original M is transferred can thus be formed on the mesa portion Sa of the substrate S.

### [Alignment Driving Amount Determination Method]

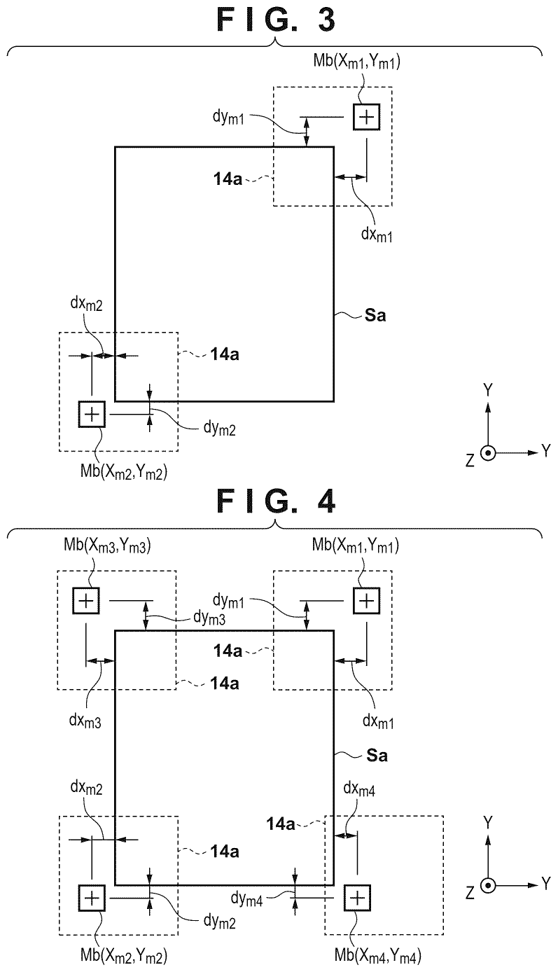

The alignment driving amount determination method in step S14 will be described next. FIGS. 3 and 4 are views showing the original M and the substrate S viewed from the +Z direction. As shown in FIGS. 3 and 4, the mesa portion Sa of the substrate S can be formed into a rectangular shape viewed from the original side. In this case, the pattern region PA of the original M to be caused to face the mesa portion Sa of the substrate S in imprint processing also has a rectangular shape. Also, on the original M, a plurality of marks Mb are arranged outside the pattern region PA. The plurality of marks Mb can be arranged such that at least one mark is arranged with respect to each of at least two of the four sides forming the mesa portion Sa in the rectangular shape. In the example shown in FIG. 3, the mark Mb is provided for each of two corners of the mesa portion Sa in the rectangular shape. The two corners preferably have a diagonal relationship. On the other hand, in the example shown in FIG. 4, the mark Mb is provided for each of four corners of the mesa portion Sa in the rectangular shape.

In this embodiment, the alignment driving amounts of the original M and the substrate S aim at reducing the position error and/or the shape error between the pattern Ma of the original M and the mesa portion Sa of the substrate S and can be determined in step S14 of the flowchart shown in FIG. 2. As described above, the alignment driving amounts can be determined based on the image captured by the image capturing device 14, in a state in which both a part of the outer edge of the mesa portion Sa of the substrate S and the mark Mb of the original M are included within the field of view of the image capturing device 14. For example, as shown in FIGS. 3 and 4, each mark Mb of the original M is arranged outside the pattern region PA of the original M such that both the corner of the mesa portion Sa of the substrate S and the mark Mb are included within a field of view 14a of the image capturing device 14.

Based on the image obtained by the image capturing device 14, the controller 18 calculates X- and Y-direction distances (dxₘ, dyₘ) between a part (for example, a corner) of the outer edge of the mesa portion Sa of the substrate S and each mark Mb of the original. At this time, to reduce the influence of defocus between the mark Mb of the original M and the mesa portion Sa of the substrate S in the image, the mark Mb of the original M is preferably arranged on a surface having the same height as the surface with the pattern Ma of the original M arranged thereon. Also, image capturing of a part of the outer edge of the mesa portion Sa of the substrate S and the mark Mb of the original M by the image capturing device 14 is preferably performed in a state in which the original M and the substrate S are close such that these are fitted in the focal depth of the image capturing device 14.

The alignment driving amount determination method in the example shown in FIG. 3 will be described first. In FIG. 3, the positions of the two marks Mb on the original M are defined as (Xₘ₁, Yₘ₁) and (Xₘ₂, Yₘ₂), and the distances from the marks Mb to the outer edge of the mesa portion Sa of the substrate S are defined as (dxₘ₁, dyₘ₁) and (dxₘ₂, dyₘ₂). In addition, the X-direction shift amount (Shift-x) for aligning the original M and the substrate S is defined as Sx, the Y-direction shift amount (Shift-y) is defined as Sy, and the RotZ-direction rotation (Rotation-z) is defined as Rz. In this case, Sx, Sy, and Rz can be determined as alignment driving amounts by

$$( \begin{matrix}{S}_{x} \\ {S}_{y} \\ {R}_{z}\end{matrix} ) = B ( \begin{matrix}{dx}_{m 1} \\ {dx}_{m 2} \\ {dy}_{m 1} \\ {dy}_{m 2}\end{matrix} ) B is the similar inverse matrix of ( \begin{matrix}1 & 0 & - {y}_{m 1} \\ 1 & 0 & - {y}_{m 2} \\ 0 & 1 & {x}_{m 1} \\ 0 & 1 & {x}_{m 2}\end{matrix} ) \qquad ( 1 )$$

Next, the alignment driving amount determination method in the example shown in FIG. 4 will be described. In FIG. 4, the positions of the four marks Mb on the original M are defined as (Xₘ₁, Yₘ₁), (Xₘ₂, Yₘ₂), (Xₘ₃, Yₘ₃), and (Xₘ₄, Yₘ₄). The distances from the marks Mb to the outer edge of the mesa portion Sa of the substrate S are defined as (dxₘ₁, dyₘ₁), (dxₘ₂, dyₘ₂), (dxₘ₃, dyₘ₃), and (dxₘ₄, dyₘ₄). In addition, the X-direction shift amount (Shift-x) for aligning the original M and the substrate S is defined as Sx, the Y-direction shift amount (Shift-y) is defined as Sy, and the RotZ-direction rotation (Rotation-z) is defined as Rz. Furthermore, the skew (Skew) for aligning the original M and the substrate S is defined as Sk, the X-direction magnification (MagX) is defined as Mx, and the Y-direction magnification is defined as My. In this case, Sx, Sy, Rz, Sk, Mx, and My can be determined as alignment driving amounts by

$$( \begin{matrix}{S}_{x} \\ {S}_{y} \\ {R}_{z} \\ {S}_{k} \\ {M}_{x} \\ {M}_{y}\end{matrix} ) = C ( \begin{matrix}{dx}_{m 1} \\ {dx}_{m2} \\ {dx}_{m 3} \\ {dx}_{m 4} \\ {dy}_{m 1} \\ {dy}_{m 2} \\ {dy}_{m 3} \\ {dy}_{m 4}\end{matrix} ) C is the similar inverse matrix of ( \begin{matrix}1 & 0 & - {y}_{m 1} & {y}_{m 1} & {x}_{m 1} & 0 \\ 1 & 0 & - {y}_{m 2} & {y}_{m 2} & {x}_{m 2} & 0 \\ 1 & 0 & - {y}_{m 3} & {y}_{m 3} & {x}_{m 3} & 0 \\ 1 & 0 & - {y}_{m 4} & {y}_{m 4} & {x}_{m 4} & 0 \\ 0 & 1 & {x}_{m 1} & {x}_{m 1} & 0 & {y}_{m 1} \\ 0 & 1 & {x}_{m 2} & {x}_{m 2} & 0 & {y}_{m 2} \\ 0 & 1 & {x}_{m 3} & {x}_{m 3} & 0 & {y}_{m 3} \\ 0 & 1 & {x}_{m 4} & {x}_{m 4} & 0 & {y}_{m 4}\end{matrix} ) \qquad ( 2 )$$

The determined alignment driving amounts can be used in the alignment step (S16) performed after the supply step (S15). More specifically, the controller 18 supplies the imprint material IM onto the mesa portion Sa of the substrate S and then, when arranging the substrate S under the original M, corrects the relative position between the original M and the substrate S based on the alignment driving amounts Sx, Sy, and Rz. This can reduce the alignment error between the pattern Ma of the original M and the mesa portion Sa of the substrate S. By performing the subsequent contact step (S17), curing step (S18), and separation step (S19), the pattern Ma of the original M can accurately be transferred to the imprint material IM on the mesa portion Sa of the substrate S.

As described above, in the imprint apparatus 100 according to this embodiment, alignment between the original M and the substrate S is controlled based on the image captured by the image capturing device 14, such that the image includes a part of the outer edge of the mesa portion Sa of the substrate S and the mark Mb of the original M. When an image including a part of the outer edge of the mesa portion Sa of the substrate S and the mark Mb of the original M is captured by the same image capturing device 14, and alignment between the original M and the substrate S is controlled based on the thus obtained image, the alignment accuracy can be improved. According to this embodiment, since alignment between the original M and the substrate S can accurately be performed without providing marks on the substrate S, a process of forming marks on the substrate S can be omitted, and it can be advantageous from the viewpoint of cost. Also, in the imprint apparatus 100 according to this embodiment, in a state in which both a part of the outer edge of the mesa portion Sa of the substrate S and the mark Mb of the original M are included within the field of view of the image capturing device 14, images of these may simultaneously be captured by the image capturing device 14. The alignment accuracy can further be improved by controlling alignment between the original M and the substrate S based on the thus obtained image.

### Second Embodiment

The second embodiment according to the present disclosure will be described. In the above-described first embodiment, an example in which the alignment driving amounts are determined before the supply step of supplying the imprint material IM onto the mesa portion Sa of the substrate S has been described. In this embodiment, an example in which the alignment driving amounts are determined after the supply step will be described. Note that this embodiment basically takes over the first embodiment, and matters other than those to be mentioned below can comply with the first embodiment.

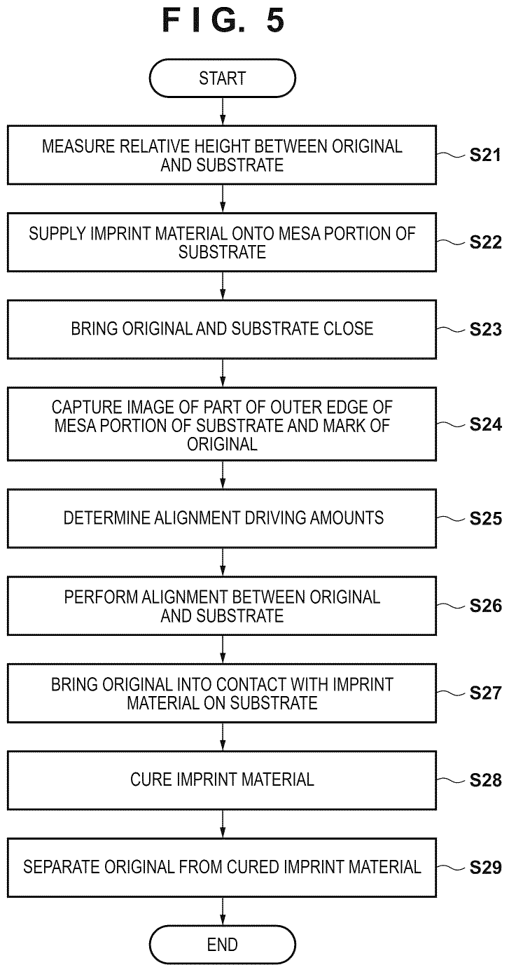

FIG. 5 is a flowchart showing imprint processing for producing a replica mold in this embodiment. The flowchart shown in FIG. 5 can be executed by the controller 18.

In step S21, the controller 18 measures the relative height between an original M and a substrate S. Next, in step S22, the controller 18 supplies an imprint material IM onto a mesa portion Sa of the substrate S using a liquid supply unit 15 (supply step). Steps S21 and S22 are the same as steps S11 and S15 of the flowchart shown in FIG. 2, respectively, and a detailed description thereof will be omitted here.

In step S23, using a first positioning mechanism 11, the controller 18 arranges the substrate S under the original M and brings a mark Mb of the original M close to the mesa portion Sa of the substrate S. In step S24, in a state in which the original M and the substrate S are not in contact, the controller 18 captures an image including a part of the outer edge of the mesa portion Sa of the substrate S and the mark Mb of the original M by an image capturing device 14. In step S25, the controller 18 determines (calculates) alignment driving amounts based on the image obtained by the image capturing device 14 in step S24. Next, in step S26, the controller 18 performs alignment between the original M and the substrate S based on the alignment driving amounts determined in step S25 (alignment step). Steps S23 to S26 are the same as steps S12 to S14 and S16 of the flowchart shown in FIG. 2, respectively, and a detailed description thereof will be omitted here.

In step S27, the controller 18 decreases the interval between the original M and the substrate S, thereby bringing the original M into contact with the imprint material IM on the substrate S (mesa portion Sa) (contact step). In step S28, in a state in which the original M and the imprint material IM on the substrate S (mesa portion Sa) are in contact, the controller 18 cures the imprint material IM (curing step). Next, in step S29, the controller 18 increases the interval between the original M and the substrate S, thereby separating the original M from the cured imprint material IM on the substrate S (mesa portion Sa) (separation step). Steps S27 to S29 are the same as steps S17 to S19 of the flowchart shown in FIG. 2, respectively, and a detailed description thereof will be omitted here.

As described above, in this embodiment, the alignment driving amounts are determined after the supply step, and alignment between the original M and the substrate S is controlled based on the alignment driving amounts. According to this embodiment as well, the alignment accuracy can be improved, and it can be advantageous from the viewpoint of cost, like the first embodiment.

### Third Embodiment

The third embodiment according to the present disclosure will be described. In the above-described first embodiment, an example in which the substrate S is held by the first positioning mechanism 11, and the original M is held by the second positioning mechanism 12 has been described. In this embodiment, an example in which an original M and the substrate S are replaced with each other will be described. That is, in this embodiment, not the substrate S but the original M is held by a first positioning mechanism 11, and not the original M but the substrate S is held by a second positioning mechanism 12. Note that this embodiment basically takes over the first embodiment, and matters other than those to be mentioned below can comply with the first embodiment.

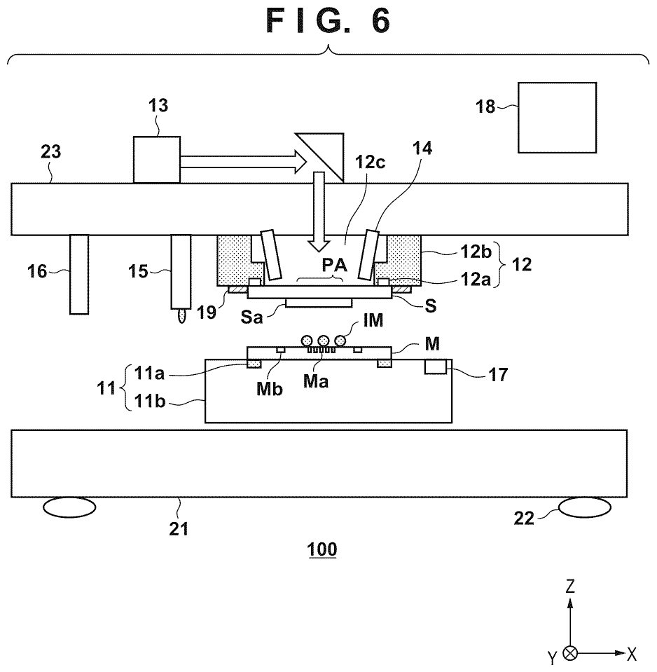

FIG. 6 schematically shows an example of the configuration of an imprint apparatus 100 according to this embodiment. In the imprint apparatus 100 according to this embodiment, as described above, the original M is held by the first positioning mechanism 11, and the substrate S is held by the second positioning mechanism 12. In this case, an image capturing device 14 captures an image of the original M held by the first positioning mechanism 11 through the substrate S held by the second positioning mechanism 12. A liquid supply unit 15 supplies an imprint material IM onto the original M (pattern region PA) held by the first positioning mechanism 11. A first height measurement unit 16 measures the surface height of the original M held by the first positioning mechanism 11. A second height measurement unit 17 measures the surface height of the substrate S held by the second positioning mechanism 12.

Imprint processing for producing a replica mold in this embodiment can be performed in accordance with the flowchart shown in FIG. 2. In this embodiment, the original M and the substrate S are replaced with each other in the description using the flowchart of FIG. 2. In this embodiment as well, alignment between the original M and the substrate S is controlled based on an image captured by the image capturing device 14, such that the image includes a part of the outer edge of a mesa portion Sa of the substrate S and a mark Mb of the original M. Also, in this embodiment, in a state in which both a part of the outer edge of the mesa portion Sa of the substrate S and the mark Mb of the original M are included within the field of view of the image capturing device 14, images of these may simultaneously be captured by the image capturing device 14. Even if the original M and the substrate S are replaced with each other as in this embodiment, the alignment accuracy can be improved, and it can be advantageous from the viewpoint of cost, like the first embodiment.

### Fourth Embodiment

The fourth embodiment according to the present disclosure will be described. In this embodiment, an example in which an original M is held by a first positioning mechanism 11, and a substrate S is held by a second positioning mechanism 12, like the above-described third embodiment, will be described. Also, in this embodiment, the alignment driving amounts are determined after the supply step, like the above-described second embodiment. Note that this embodiment basically takes over the first embodiment, and matters other than those to be mentioned below can comply with the first embodiment. Also, in this embodiment, the second embodiment can also be applied.

An example of the configuration of an imprint apparatus 100 according to this embodiment is the same as described with reference to FIG. 6 in the third embodiment. Imprint processing for producing a replica mold in this embodiment can be performed in accordance with the flowchart shown in FIG. 5. In this embodiment, the original M and the substrate S are replaced with each other in the description using the flowchart of FIG. 5. In this embodiment as well, alignment between the original M and the substrate S is controlled based on an image captured by an image capturing device 14, such that the image includes a part of the outer edge of a mesa portion Sa of the substrate S and a mark Mb of the original M. Also, in this embodiment, in a state in which both a part of the outer edge of the mesa portion Sa of the substrate S and the mark Mb of the original M are included within the field of view of the image capturing device 14, images of these may simultaneously be captured by the image capturing device 14. Even if the original M and the substrate S are replaced with each other as in this embodiment, the alignment accuracy can be improved, and it can be advantageous from the viewpoint of cost, like the second embodiment.

### <Embodiment of Article Manufacturing Method>

An article manufacturing method according to the embodiment of the present disclosure is suitable for manufacturing an article, for example, a microdevice such as a semiconductor device or an element having a fine structure. The article manufacturing method according to this embodiment includes a formation step of forming a pattern on a substrate using the above-described lithography apparatus (for example, the imprint apparatus), a processing step of processing the substrate that has undergone the formation step, and a manufacturing step of manufacturing an article from the substrate that has undergone the processing step. The article manufacturing method also includes other known processes (oxidation, deposition, vapor deposition, doping, planarization, etching, resist removal, dicing, bonding, and packaging). The article manufacturing method according to this embodiment is advantageous in at least one of the performance, quality, productivity, and production cost of the article, as compared to conventional methods.

### OTHER EMBODIMENTS

Embodiments of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-042625, filed on Mar. 17, 2025, which is hereby incorporated by reference herein in its entirety.

What is claimed is:

1. An alignment apparatus for performing alignment between an original and a substrate, the original having a pattern and a mark, and the substrate having a convex portion to which the pattern is to be transferred, comprising:
an image capturing device configured to capture, through one of the original and the substrate, an image of the other of the original and the substrate; and
at least one processor or circuit configured to function as:
a controller configured to control the alignment based on an image obtained by the image capturing device, the image including a part of an outer edge of the convex portion of the substrate and the mark of the original.

2. The apparatus according to claim 1, wherein the image is obtained by the image capturing device in a state in which both the part of the outer edge of the convex portion of the substrate and the mark of the original are included within a field of view of the image capturing device.

3. The apparatus according to claim 2, wherein the pattern is arranged in a region of the original caused to face the convex portion of the substrate, and
the mark is arranged outside the region of the original such that both the part of the outer edge of the convex portion and the mark are included within the field of view of the image capturing device.

4. The apparatus according to claim 3, wherein the convex portion of the substrate has a rectangular shape when viewed from a side of the original, and
the mark is arranged outside the region of the original such that both a corner of the convex portion and the mark are included within the field of view of the image capturing device.

5. The apparatus according to claim 4, wherein on the original, the mark is arranged for each of at least two corners of the convex portion, and
the controller controls the alignment based on the image obtained by the image capturing device for each mark.

6. The apparatus according to claim 3, wherein the convex portion of the substrate has a rectangular shape when viewed from a side of the original,
on the original, the mark is arranged for each of at least two sides of the convex portion, and
the controller controls the alignment based on the image obtained by the image capturing device for each mark.

7. The apparatus according to claim 1, wherein the image capturing device captures the image including the part of the outer edge of the convex portion of the substrate and the mark of the original, in a state in which the original and the substrate are not in contact.

8. The apparatus according to claim 1, wherein on the original, the mark is arranged in a plane that has the same height as a surface with the pattern arranged thereon.

9. The apparatus according to claim 1, wherein the controller controls the alignment such that a position error and/or a shape error between the original and the substrate is reduced.

10. The apparatus according to claim 1, further comprising a driver configured to relatively drive the original and the substrate,
wherein the controller controls the alignment by relatively driving the original and the substrate by the driver based on the image.

11. The apparatus according to claim 1, wherein the original includes a master mold, and
the substrate includes a blank mold to which the pattern of the master mold that is the original is transferred.

12. A lithography apparatus for forming a pattern on a substrate using an original, comprising
an alignment apparatus for performing alignment between the original and the substrate, the original having a pattern and a mark, and the substrate having a convex portion to which the pattern is to be transferred,
wherein the alignment apparatus includes:
an image capturing device configured to capture, through one of the original and the substrate, an image of the other of the original and the substrate; and
at least one processor or circuit configured to function as:
a controller configured to control the alignment based on an image obtained by the image capturing device, the image including a part of an outer edge of the convex portion of the substrate and the mark of the original,
wherein the pattern of the original is transferred onto the substrate in a state in which the alignment is performed by the alignment apparatus.

13. An article manufacturing method comprising:
forming a pattern on a substrate using an original, by a lithography apparatus;
processing the substrate that has undergone the forming; and
manufacturing an article from the substrate that has undergone the processing,
wherein the forming includes performing alignment between the original and the substrate, the original having a pattern and a mark, and the substrate having a convex portion to which the pattern is to be transferred,
wherein the performing alignment includes:
capturing, through one of the original and the substrate, an image of the other of the original and the substrate; and
controlling the alignment based on the image obtained in the capturing, the image including a part of an outer edge of the convex portion of the substrate and the mark of the original.
